(19) United States
(12) Patent Application Publication
(10) Pub. No.: US 2025/0223153 A1
(43) Pub. Date: Jul. 10, 2025

(54) SEMICONDUCTOR STRUCTURE AND METHOD OF MAKING

(71) Applicant: Taiwan Semiconductor Manufacturing Company Limited, Hsin-Chu (TW)

(72) Inventor: Yu-Hsun LI, Yunlin County (TW)

(21) Appl. No.: 18/406,543

(22) Filed: Jan. 8, 2024

(51) Int. Cl. B81B 3/00; B81C 1/00

(52) U.S. Cl. CPC B81B 3/0078; B81C 1/00666; B81B 2203/0136; B81B 2207/015; B81C 2203/0735

(57) ABSTRACT

A micro-electromechanical systems (MEMS) structure and method of making are provided. In an embodiment, the MEMS structure includes a first stationary element, a second stationary element, a cap structure connecting the first stationary element and the second stationary element, and a moveable element between the first stationary element and the second stationary element and under the cap structure. A first spring includes a first layer exhibiting tensile stress and a second layer exhibiting compressive stress and spans between the cap structure and the moveable element. A second spring includes a third layer exhibiting tensile stress and a fourth layer exhibiting compressive stress and spans between the first stationary element and the moveable element. The first layer has a first thickness and the second layer has a second thickness of at least 50 percent of the first thickness.

### BACKGROUND

Micro-electromechanical systems (MEMS) combine mechanical and electronic components on a semiconductor structure. A MEMS structure can be used as a sensor, such as a pressure sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-27 illustrate a semiconductor device at various stages of fabrication, in accordance with some embodiments.

FIG. 28 illustrates springs, in accordance with some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

According to some embodiments, a microelectromechanical systems (MEMS) device is formed. Springs are formed between stationary elements and moveable elements of the MEMS devices to reduce susceptibility of the MEMS device to vibration. In some embodiments, the springs comprise alternating layers of metal and dielectric. In some embodiments, an organic layer is formed between two sets of layers of metal and dielectric. An annealing process is performed to introduce stress into the layers. The dielectric layer exhibits compressive stress and the metal layer exhibits tensile stress, thereby causing spring-like behavior. Springs may be formed along interfaces between the stationary elements and moveable elements of the MEMS devices in the x-direction, the y-direction, and the z-direction.

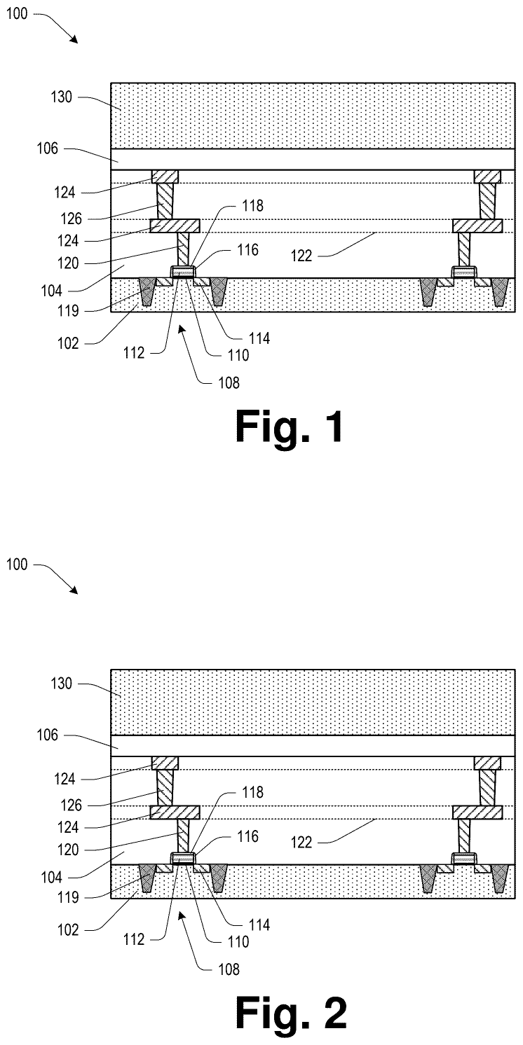

FIGS. 1-27 illustrate a semiconductor structure 100 at various stages of fabrication, in accordance with some embodiments. FIGS. 1-27 illustrate cross-section views of the semiconductor structure 100 at various stages of fabrication. In some embodiments, the semiconductor structure 100 is a MEMS device. The semiconductor structure 100 includes a substrate layer 102, an interlayer dielectric layer 104 over the substrate layer 102, and a bonding dielectric layer 106 over the interlayer dielectric layer 104. In some embodiments, the bonding dielectric layer 106 comprises silicon dioxide. The bonding dielectric layer 106 provides an interface for bonding another semiconductor wafer.

The substrate layer 102 comprises at least one of an epitaxial layer, a single crystalline semiconductor material such as, but not limited to at least one of Si, Ge, SiGe, InGaAs, GaAs, InSb, GaP, GaSb, InAIAs, GaSbP, GaAsSb, and InP, a silicon-on-insulator (SOI) structure, a wafer, or a die formed from a wafer. In some embodiments, the substrate layer 102 comprises at least one of crystalline silicon or other suitable materials. The substrate layer 102 may be a silicon-on-insulator (SOI) substrate comprising a layer of a semiconductor material (e.g., silicon, germanium and the like) formed over an insulator layer (e.g., buried oxide and the like), which is formed in a silicon substrate. Other substrates that may be used include multi-layered substrates, gradient substrates, hybrid orientation substrates, the like, or a combination thereof. Other structures and/or configurations of the substrate layer 102 are within the scope of the present disclosure.

According to some embodiments, the semiconductor structure 100 comprises devices 108 formed on or within the substrate layer 102. In some embodiments, the devices 108 each comprise a gate dielectric layer 110 a gate electrode 112, source/drain regions 114, a sidewall spacer 116, a gate cap layer 118, etc. According to some embodiments, the gate dielectric layer 110, and the gate electrode 112 are formed using a gate replacement process. A sacrificial gate structure comprising a sacrificial gate dielectric layer, a sacrificial gate electrode layer, such as a polysilicon layer, and a hard mask layer are formed. In some embodiments, a patterning process is performed to pattern the hard mask layer corresponding to a pattern of gate structures to be formed, and an etch process is performed using the patterned hard mask layer to etch the sacrificial gate electrode layer and the sacrificial gate dielectric layer to define the sacrificial gate structure. In some embodiments, remaining portions of the hard mask layer form a cap layer over the portions of the sacrificial gate electrode layer remaining after the etch process. The sacrificial gate structure is later replaced with a replacement gate dielectric layer, such as the gate dielectric layer 110 and a replacement gate electrode, such as the gate electrode 112.

In some embodiments, the gate dielectric layer 110 comprises a high-k dielectric material. As used herein, the term “high-k dielectric” refers to the material having a dielectric constant, k, greater than or equal to about 3.9, which is the k value of SiO₂. The high-k dielectric material may be any suitable material. Examples of the high-k dielectric material include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2. In some embodiments, the gate dielectric layer 110 comprises a native oxide layer formed by exposure of the semiconductor structure 100 to oxygen at various points in the process flow, causing the formation of silicon dioxide on exposed surfaces of the substrate layer 102. In some embodiments, an additional layer of dielectric material, such as silicon dioxide, a high-k dielectric material, or other suitable material, is formed over the native oxide to form the gate dielectric layer 110.

In some embodiments, the gate electrode 112 comprises a barrier layer, one or more work function material layers, a seed layer, a metal fill layer, or other suitable layers. In some embodiments, the metal fill layer comprises tungsten, aluminum, copper, cobalt, or other suitable material. In some embodiments, the gate dielectric layer 110 and the one or more layers that comprise the gate electrode 112 are deposited by at least one of atomic layer deposition (ALD), physical vapor deposition (PVD), chemical vapor deposition (CVD), low pressure chemical vapor deposition (LPCVD), plasma enhanced chemical vapor deposition (PECVD), atomic layer chemical vapor deposition (ALCVD), ultrahigh vacuum chemical vapor deposition (UHVCVD), reduced pressure chemical vapor deposition (RPCVD), molecular beam epitaxy (MBE), or other suitable techniques. In some embodiments, the gate electrode 112 is recessed and the gate cap layer 118 is formed in the recess.

In some embodiments, the sidewall spacer 116 is formed adjacent the gate dielectric layer 110 and the gate electrode 112. In some embodiments, the sidewall spacer 116 is formed by depositing a spacer layer over the sacrificial gate structure and performing an anisotropic etch process to remove horizontal portions of the spacer layer. In some embodiments, the sidewall spacer 116 comprises silicon nitride or other suitable materials.

In some embodiments, the source/drain regions 114 are formed in the substrate layer 102 after forming the sacrificial gate structure. For example, in some embodiments, portions of the substrate layer 102 are doped through an implantation process to form the source/drain regions 114. In some embodiments, an etch process is performed to recess the substrate layer 102 adjacent the sidewall spacer 116, and an epitaxial growth process is performed to form the source/drain regions 114.

In an embodiment, one or more shallow trench isolation (STI) structures 119 are formed within the substrate layer 102. In some embodiments, the STI structures 119 are formed by forming at least one mask layer over the substrate layer 102. In some embodiments, the at least one mask layer comprises a layer of oxide material over the substrate layer 102 and a layer of nitride material over the layer of oxide material, and/or one or more other suitable layers. At least some of the at least one mask layer is removed to define an etch mask for use as a template to etch the substrate layer 102 to form trenches. A dielectric material is formed in the trenches to define the STI structures 119. In some embodiments, the STI structures 119 include multiple layers, such as an oxide liner, a nitride liner formed over the oxide liner, an oxide fill material formed over the nitride liner, and/or other suitable materials.

In some embodiments, a fill material, such as the oxide fill material, is formed using a high density (HDP) plasma process. The HDP process uses precursor gases comprising at least one of silane (SiH₄), oxygen, argon, or other suitable gases. The HDP process includes a deposition component, which forms material on surfaces defining the trench, and a sputtering component, which removes or relocates deposited material. A deposition-to-sputtering ratio depends on gas ratios employed during the deposition component. According to some embodiments, argon and oxygen act as sputtering sources, and the particular values of the gas ratios are determined based on an aspect ratio of the trench. After forming the fill material, an annealing process is performed to densify the fill material. In some embodiments, the STI structures 119 generate compressive stress. In some embodiments, the STI structures 119 are formed prior to forming the devices 108. Other structures and/or configurations of the STI structures 119 are within the scope of the present disclosure.

In some embodiments, the devices 108 are formed using the same materials and layer thicknesses. In some embodiments, different materials and/or thicknesses may be used due to the different voltage domains. For example, the material and/or thickness of the gate dielectric layers 110 may differ from one another. Although the devices 108 are illustrated as being adjacent one other, in some embodiments, the devices 108 are formed in different regions. For example, if the gate dielectric layers 110 vary in thickness or material, the differing devices 108 may be formed in different regions. In some embodiments, the materials of the gate electrode 112 may also differ. Other structures and configurations of the devices 108 are within the scope of the present disclosure. For example, the devices 108 may be fin field-effect transistor (finFET) devices, nanosheet devices, nanowire devices, or some other suitable device.

In some embodiments, a portion of the interlayer dielectric layer 104 is formed over the devices 108. In some embodiments, the interlayer dielectric layer 104 is formed prior to forming the replacement gate structures, if applicable. In some embodiments, the interlayer dielectric layer 104 comprises silicon dioxide or a low-k dielectric material. In some embodiments, the interlayer dielectric layer 104 comprises one or more layers of low-k dielectric material. Low-k dielectric materials have a k value lower than about 3.9. In some embodiments, the material for the interlayer dielectric layer 104 comprise at least one of Si, O, C, or H, such as SiCOH, SiOC, oxygen-doped SiC (ODC), nitrogen-doped SiC (NDC), plasma-enhanced oxide (PEOX), or other suitable materials. A low-k dielectric material is, in some embodiments, further characterized or classified as ultra low-k (ULK), extra low-k (ELK), or extreme low-k (XLK), where the classification is generally based upon the k value. For example, ULK generally refers to materials with a k value of between about 2.7 to about 2.4, ELK generally refers to materials with a k value of between about 2.3 to about 2.0, and XLK generally refers to materials with a k value of less than about 2.0. Organic material, such as polymers, may be used for the interlayer dielectric layer 104. In some embodiments, the interlayer dielectric layer 104 comprises one or more layers of a carbon-containing material, organo-silicate glass, a porogen-containing material, or combinations thereof. The interlayer dielectric layer 104 comprises nitrogen in some embodiments. In some embodiments, the interlayer dielectric layer 104 is formed by using, for example, at least one of CVD, PECVD, LPCVD, ALCVD, a spin-on technology, or some other suitable process.

In some embodiments, the semiconductor structure 100 comprises one or more conductive contacts 120 formed in the interlayer dielectric layer 104. The conductive contacts 120 are formed in any number of ways, such as by a single damascene process, a dual damascene process, a trench silicide process, or some other suitable process. In some embodiments, the conductive contacts 120 contact the gate electrodes 112 and additional contacts (not shown) are formed to contact the source/drain regions 114 in different positions along the axial lengths of the devices 108, such as into or out of the page. In some embodiments, the conductive contacts 120 comprise a barrier layer, a seed layer, a metal fill layer, or other suitable layers. In some embodiments, the metal fill layer comprises tungsten, aluminum, copper, cobalt, or other suitable material. In some embodiments, the devices 108, the conductive contacts 120, and the interlayer dielectric layer 104 define a device layer of the semiconductor structure 100. Other structures and configurations of the conductive contacts 120 are within the scope of the present disclosure.

In some embodiments, the semiconductor structure 100 comprises one or more metallization layers in the interlayer dielectric layer 104 over the device layer. Any number of metallization layers are contemplated. In some embodiments, different metallization layers are separated by etch stop layers 122 to allow etch control for forming various conductive structures 124, 126 in the interlayer dielectric layer 104. The etch stop layers 122 comprise a dielectric material having a different etch selectivity from the interlayer dielectric layer 104. In some embodiments, at least one of the etch stop layers 122 comprises SiN, SiCN, SiCO, CN, etc., alone or in combination. The etch stop layers 122 are formed in any number of ways, such as by thermal growth, chemical growth, ALD, CVD, PECVD, or some other suitable process.

The conductive structures extend through their respective portions of the interlayer dielectric layer 104 in the associated metallization layer. In some embodiments, some of the conductive structures 124 comprise conductive lines and the conductive structures 126 comprise conductive vias. In some embodiments, the conductive structures 124, 126 comprise a barrier layer, a seed layer, a metal fill layer, or other suitable layers. In some embodiments, the metal fill layer comprises tungsten, aluminum, copper, cobalt, or other suitable material. Other structures and configurations of the conductive structures 124, 126 are within the scope of the present disclosure.

In some embodiments, the devices 108 are portions of a circuit implemented by the semiconductor structure 100. In some embodiments, the circuit comprises a sensor circuit comprising at least one of an image sensor, a complementary metal-oxide-semiconductor (CMOS) image sensor (CIS), a backside CIS, a proximity sensor, a time of flight (ToF) sensor, an indirect ToF (iToF) sensor, a backside illumination (BSI) sensor, or other type of sensor. In some embodiments, the circuit comprises a logic circuit, a light-emitting diode (LED) circuit, a liquid-crystal display (LCD) circuit, a random access memory (RAM) circuit, or other type of circuit. Other structures and/or configurations of the semiconductor structure 100 are within the scope of the present disclosure.

Referring to FIG. 2, a semiconductor layer 130 is bonded to the bonding dielectric layer 106, in accordance with some embodiments. The semiconductor layer 130 may be provided as a separate semiconductor wafer or a die formed from a semiconductor wafer. The semiconductor layer 130 may include at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP. During the bonding process to attach the semiconductor layer 130 to the bonding dielectric layer 106, heat and/or pressure may be applied to the semiconductor layer 130 causing a bond to be formed between the semiconductor layer 130 and the bonding dielectric layer 106. Other substrates that may be used include multi-layered substrates, gradient substrates, hybrid orientation substrates, the like, or a combination thereof. Other structures and/or configurations of the semiconductor layer 130 are within the scope of the present disclosure.

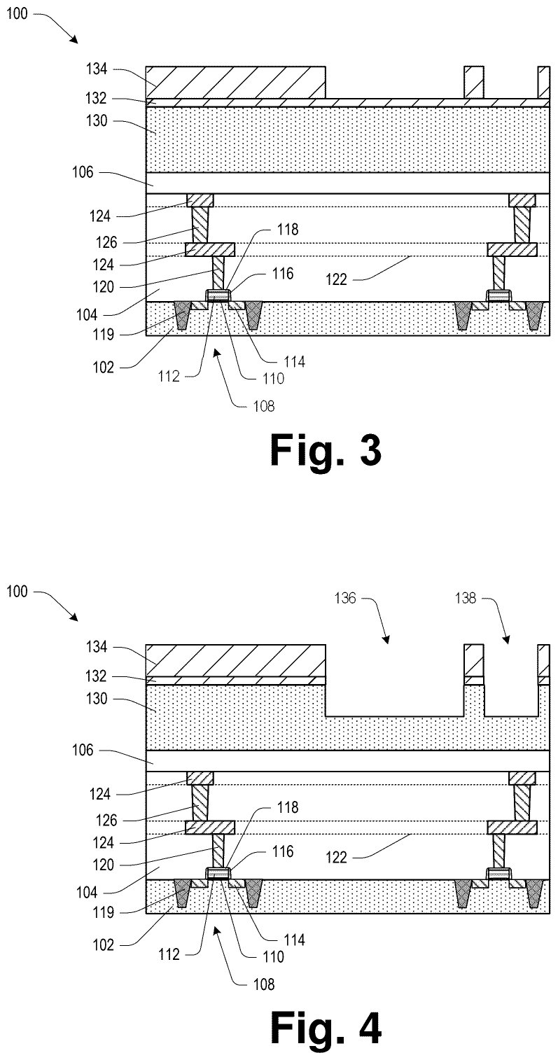

Referring to FIG. 3, a bonding dielectric layer 132 is formed over the semiconductor layer 130 and a patterned mask 134 is formed over the bonding dielectric layer 132, in accordance with some embodiments. In some embodiments, the bonding dielectric layer 132 is formed over the semiconductor layer 130 prior to bonding the semiconductor layer 130 to the bonding dielectric layer 106. Alternatively, the bonding dielectric layer 132 may be formed after bonding the semiconductor layer 130 to the bonding dielectric layer 106. The bonding dielectric layer 132 may be silicon dioxide. The patterned mask 134 may comprise a single layer, such as a photoresist layer, or a plurality of individually formed layers that together define a mask stack. In some embodiments, a mask stack comprises at least one of a hard mask layer, a bottom antireflective coating (BARC) layer, an organic planarization layer (OPL), or a photoresist layer. The hard mask layer is formed by at least one of PVD, CVD, spin on, growth, or other suitable techniques. In some embodiments, the hard mask layer comprises at least one of silicon (e.g., polycrystalline silicon), oxygen, nitrogen, or other suitable materials. In some embodiments, the BARC layer is a polymer layer that is applied using a spin coating process. In some embodiments, the OPL comprises a photo-sensitive organic polymer that is applied using a spin coating process. In some embodiments, the OPL comprises a dielectric layer. In some embodiments, the photoresist layer is formed by at least one of spinning, spray coating, or other suitable techniques. The photoresist is a negative photoresist or a positive photoresist. With respect to a negative photoresist, regions of the negative photoresist become insoluble when illuminated by a light source, such that application of a solvent to the negative photoresist during a subsequent development stage removes non-illuminated regions of the negative photoresist. A pattern formed in the negative photoresist is thus a negative image of a pattern defined by opaque regions of a template, such as a mask, between the light source and the negative photoresist. In a positive photoresist, illuminated regions of the positive photoresist become soluble and are removed via application of a solvent during development. Thus, a pattern formed in the positive photoresist is a positive image of opaque regions of the template, such as a mask, between the light source and the positive photoresist. One or more etchants have a selectivity such that the one or more etchants remove or etch away one or more layers exposed or not covered by the photoresist at a greater rate than the one or more etchants remove or etch away the photoresist. Accordingly, an opening in the photoresist allows the one or more etchants to form a corresponding opening in the one or more layers under the photoresist, and thereby transfer a pattern in the photoresist to the one or more layers under the photoresist. The photoresist is stripped or washed away after the pattern transfer. The layers of the mask stack are patterned to define the patterned mask 134. In some embodiments, the photoresist layer is exposed using a radiation source and a reticle to define a pattern in the photoresist layer, and portions of the photoresist layer are removed to define a patterned photoresist layer. The underlying OPL, BARC layer, and hard mask layer are etched using the patterned photoresist layer as a template to form the patterned mask 134 and expose portions of the bonding dielectric layer 132 under the patterned mask 134.

Referring to FIG. 4, cavities 136, 138 are formed in the bonding dielectric layer 132 and the semiconductor layer 130, in accordance with some embodiments. The cavities 136, 138 may be formed by performing an etch process using the patterned mask 134 as an etch template. The etch process may be a timed etch process.

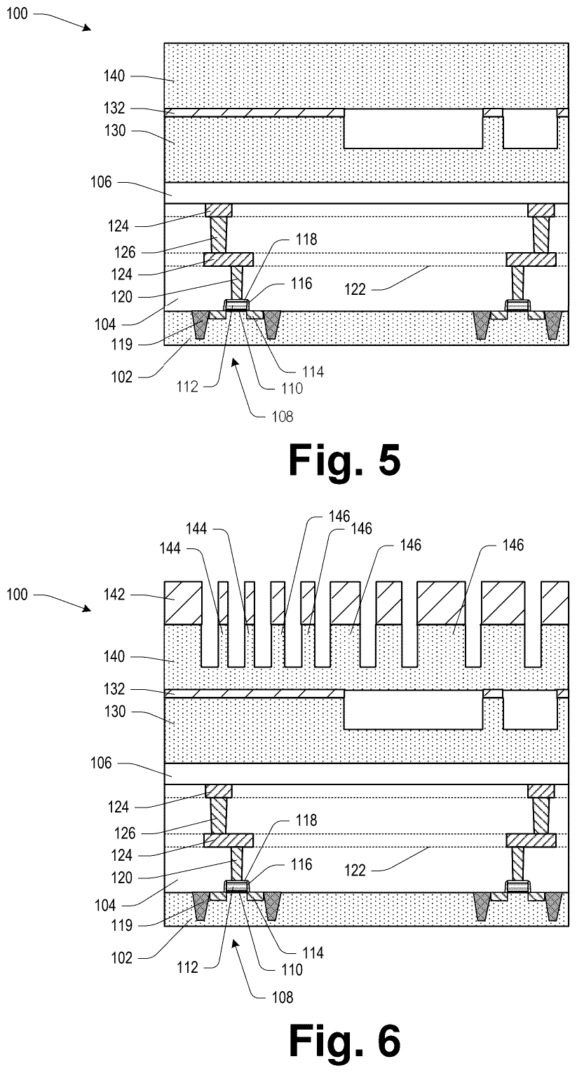

Referring to FIG. 5, the patterned mask 134 is removed and a semiconductor layer 140 is bonded to the bonding dielectric layer 132, in accordance with some embodiments. The semiconductor layer 140 may be provided as a separate semiconductor wafer or a die formed from a semiconductor wafer. The semiconductor layer 140 may include at least one of an epitaxial layer, a single crystalline semiconductor material such as, but not limited to at least one of Si, Ge, SiGe, InGaAs, GaAs, InSb, GaP, GaSb, InAlAs, GaSbP, GaAsSb, or InP. During the bonding process to attach the semiconductor layer 140 to the bonding dielectric layer 132, heat and/or pressure may be applied to the semiconductor layer 140 causing a bond to be formed between the semiconductor layer 140 and the bonding dielectric layer 132. Other substrates that may be used include multi-layered substrates, gradient substrates, hybrid orientation substrates, the like, or a combination thereof. Other structures and/or configurations of the semiconductor layer 140 are within the scope of the present disclosure.

Referring to FIG. 6, a patterned mask 142 is formed over the semiconductor layer 140 and sacrificial spacer elements 144, 146 are formed in the semiconductor layer 140, in accordance with some embodiments. The patterned mask 142 may be a photoresist mask or a stack of mask layers including at least one of a hard mask layer, a BARC layer, an OPL, or a photoresist layer comprising materials and formed as described herein. The sacrificial spacer elements 144, 146 may be formed by performing an etch process using the patterned mask 142 as an etch template to remove portions of the semiconductor layer 140. The etch process may be a timed etch process. The sacrificial spacer elements 144, 146 may have different widths.

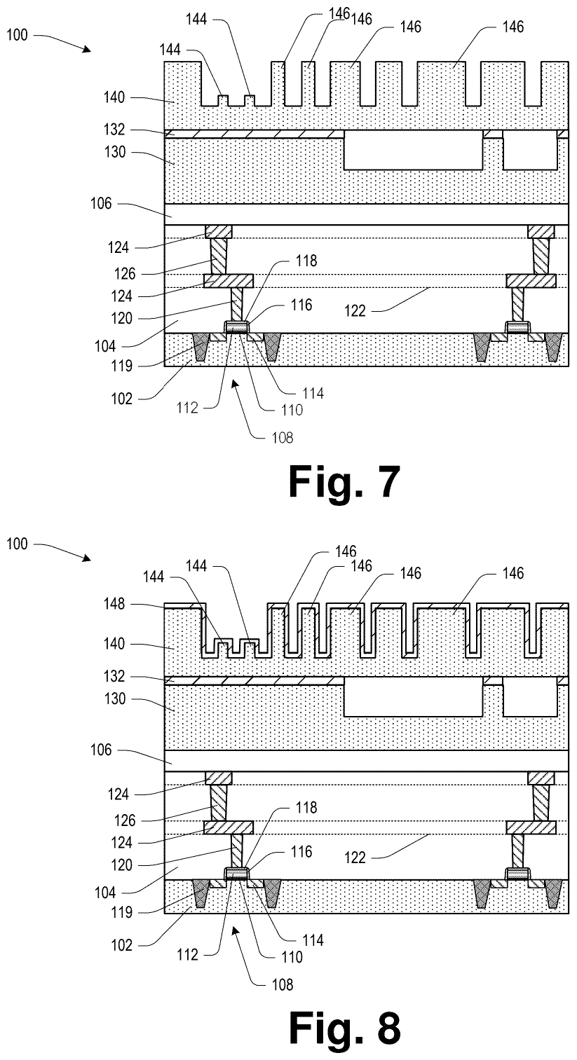

Referring to FIG. 7, the patterned mask 142 is removed and a height of the sacrificial spacer elements 144 is reduced, in accordance with some embodiments. In some embodiments, a chamfering process is performed to reduce the height of the sacrificial spacer elements 144. According to some embodiments, a chamfering process includes forming a mask over the sacrificial spacer elements 146, depositing a sacrificial material between the sacrificial spacer elements 144, performing a first etch process selective to the sacrificial material to expose the portions of the sacrificial spacer elements 144 to be removed, performing a second etch process to remove the exposed portions of the sacrificial spacer elements 144, and performing an etching and/or ashing process to remove the sacrificial material. Another technique for forming the sacrificial spacer elements 144 with a reduced height compared to the sacrificial spacer elements 146 is to form the sacrificial spacer elements 144 using separate masks and etch processes than those used for forming the sacrificial spacer elements 146.

Referring to FIG. 8, a dielectric layer 148 is formed over the sacrificial spacer elements 144, 146, in accordance with some embodiments. In some embodiments, the dielectric layer 148 is silicon dioxide. The dielectric layer 148 may be formed by using, for example, at least one of CVD, PECVD, LPCVD, ALCVD, a spin-on technology, or some other suitable process.

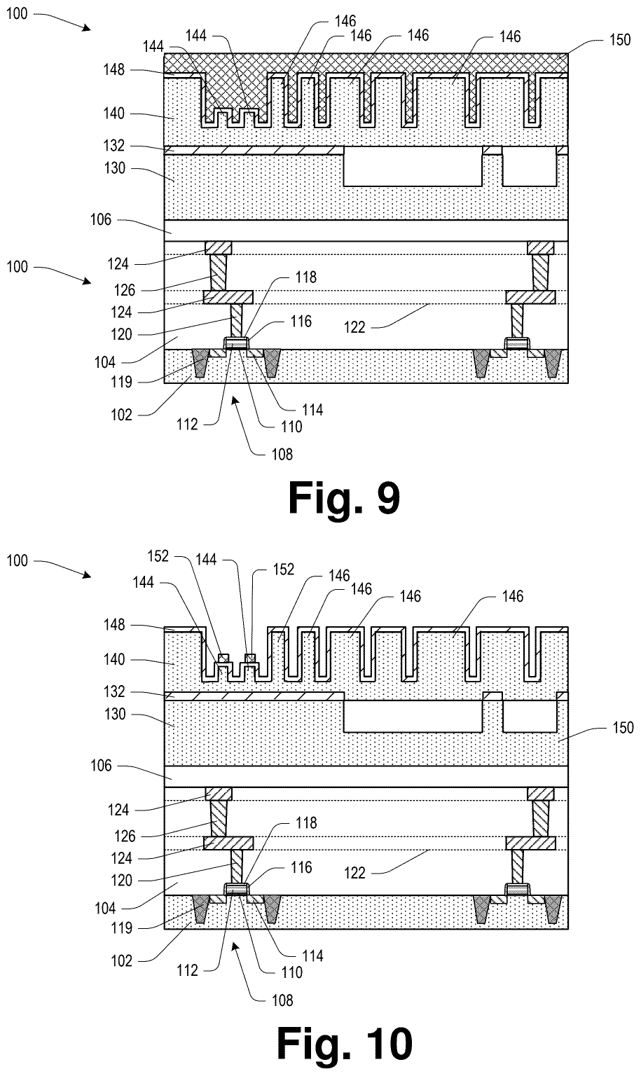

Referring to FIG. 9, a conductive layer 150 is formed between the sacrificial spacer elements 144, 146, in accordance with some embodiments. In some embodiments, the conductive layer comprises aluminum. The conductive layer 150 may be formed using a CVD process, a PVD process, a plating process, or some other suitable process.

Referring to FIG. 10, the conductive layer 150 is recessed to form conductive elements 152 over the dielectric layer 148 on the sacrificial spacer elements 144, in accordance with some embodiments. The conductive elements 152 may be formed using one or more mask and etch processes that removes portions of the conductive layer 150 between the sacrificial spacer elements 144 while preserving the conductive elements 152

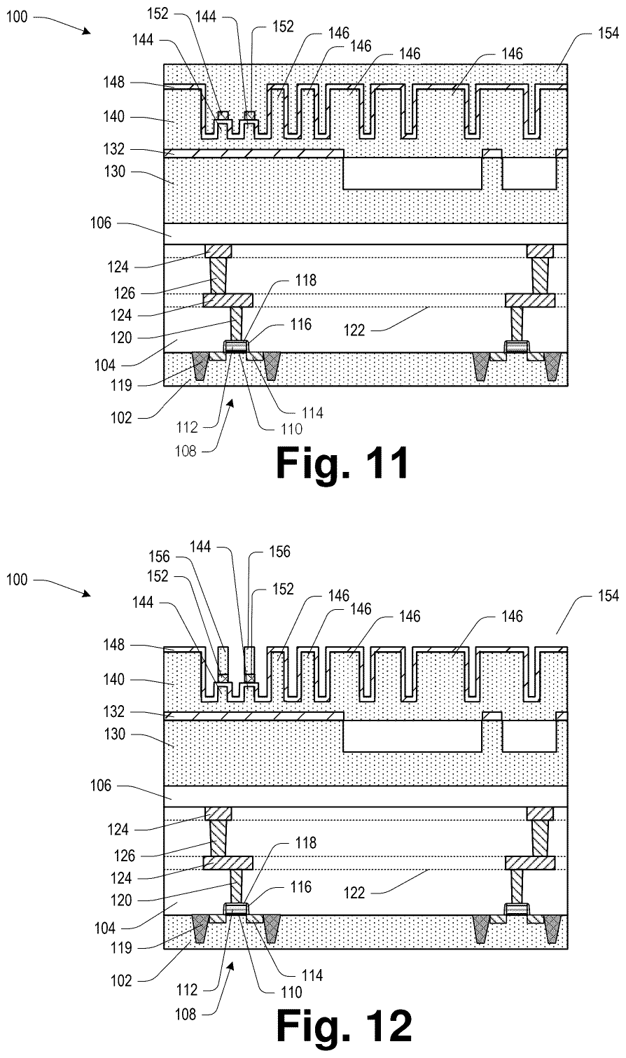

Referring to FIG. 11, a semiconductor layer 154 is formed over the conductive elements 152, over the dielectric layer 148, and between the sacrificial spacer elements 144, 146, in accordance with some embodiments. The semiconductor layer 154 comprises at least one of an epitaxial layer, a single crystalline semiconductor material such as, but not limited to at least one of Si, Ge, SiGe, InGaAs, GaAs, InSb, GaP, GaSb, InAIAs, GaSbP, GaAsSb, and InP, a silicon-on-insulator (SOI) structure, a wafer, or a die formed from a wafer. In some embodiments, the semiconductor layer 154 comprises at least one of crystalline silicon or other suitable materials.

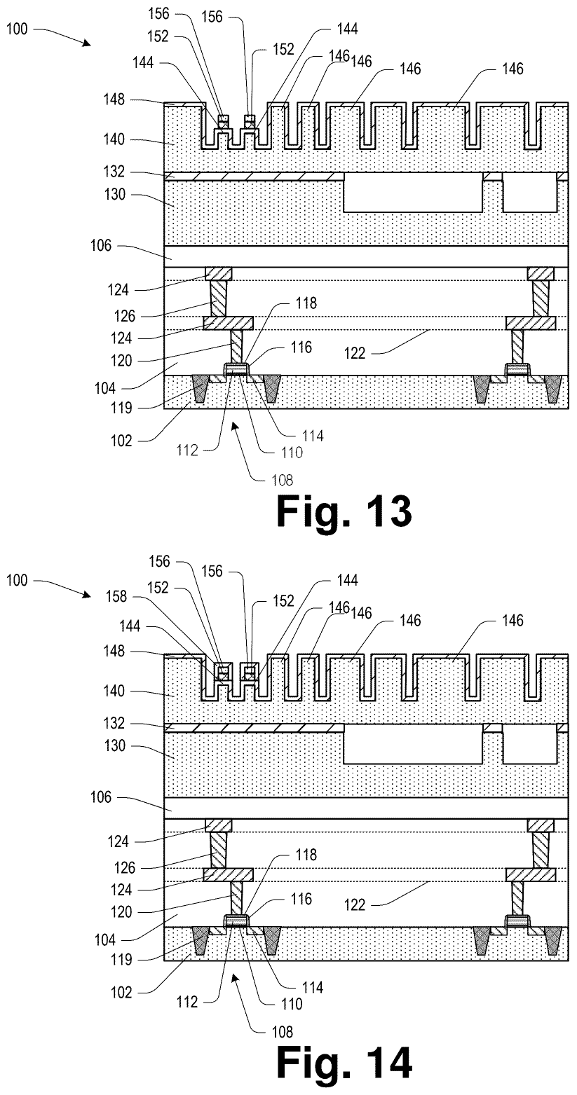

Referring to FIG. 12, the semiconductor layer 154 is patterned to form sacrificial spacer elements 156 over the conductive elements 152, in accordance with some embodiments. In some embodiments, the sacrificial spacer elements 156 are formed by planarizing the semiconductor layer 154 to remove portions of the semiconductor layer 154 above the upper surfaces of the dielectric layer 148, forming a patterned etch mask over the portions of the semiconductor layer 154 over the conductive elements 152, and performing an etch process to remove portions of the semiconductor layer 154 not covered by the patterned etch mask.

Referring to FIG. 13, the sacrificial spacer elements 156 are recessed in accordance with some embodiments. The sacrificial spacer elements 156 may be recessed by performing a timed anisotropic etch process.

Referring to FIG. 14, a dielectric layer 158 is formed over the sacrificial spacer elements 156 and the conductive elements 152, in accordance with some embodiments. In some embodiments, the dielectric layer 158 is silicon dioxide. The dielectric layer 158 may be formed by using, for example, at least one of CVD, PECVD, LPCVD, ALCVD, a spin-on technology, or some other suitable process. For ease of illustration, the thickening of the dielectric layer 148 due to formation of the dielectric layer 158 is not illustrated.

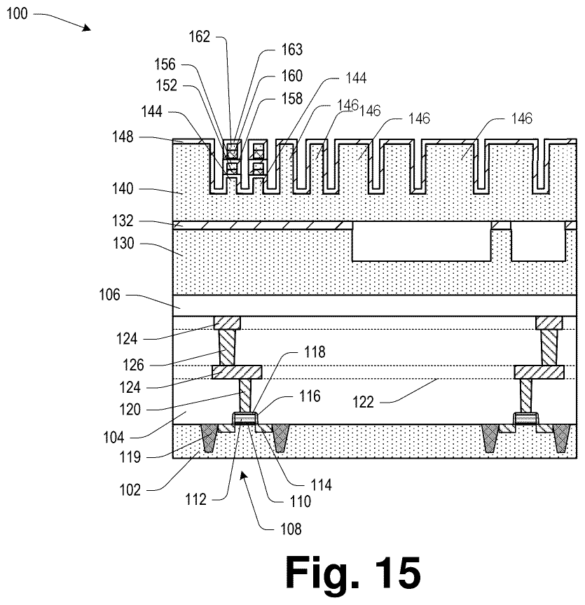

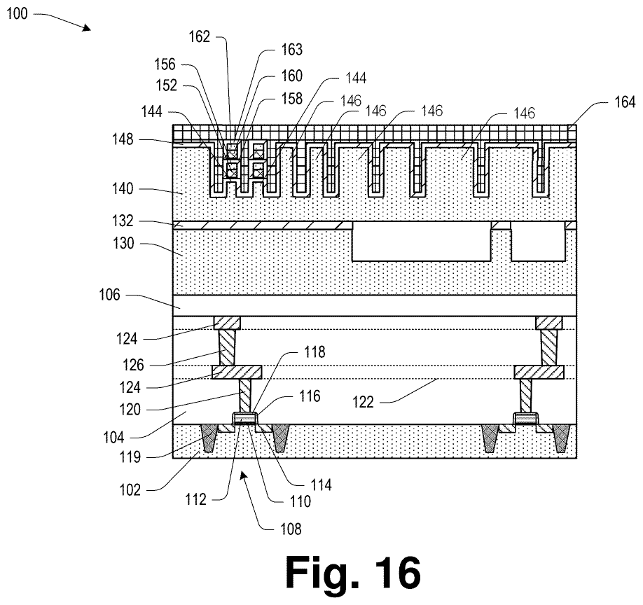

Referring to FIG. 15, the processes illustrated in FIGS. 9-14 are repeated to form conductive elements 160, sacrificial spacer elements 162 over the conductive elements 160, and a dielectric layer 163 over the sacrificial spacer elements 162 and the conductive elements 160, in accordance with some embodiments.

Referring to FIG. 16, a semiconductor layer 164 is formed over the dielectric layers 148, 158, 163 between the sacrificial spacer elements 144, 146, in accordance with some embodiments. In some embodiments, the semiconductor layer 164 exhibits different etch selectivity with respect to the sacrificial spacer elements 144, 146, 156, 162. The semiconductor layer 164 may comprise polysilicon and the sacrificial spacer elements 144, 146, 156, 162 may comprise silicon.

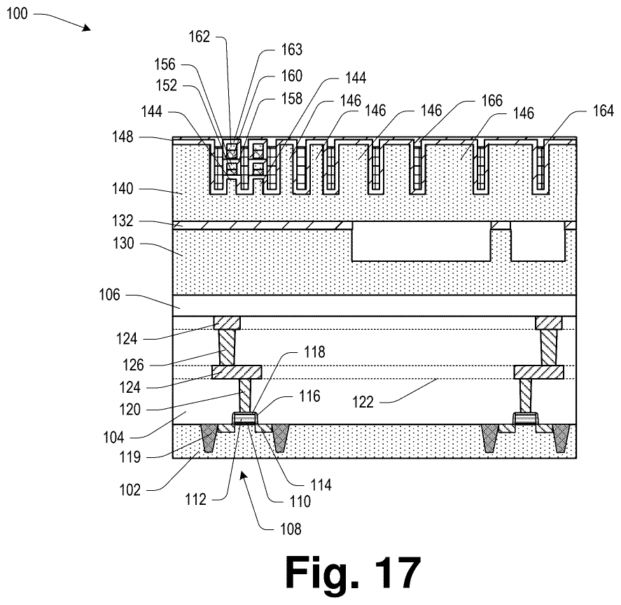

Referring to FIG. 17, the semiconductor layer 164 is recessed and a dielectric layer 166 is formed in the recesses, in accordance with some embodiments. In some embodiments, the dielectric layer 166 is silicon dioxide. The dielectric layer 166 may be formed by using, for example, at least one of CVD, PECVD, LPCVD, ALCVD, a spin-on technology, or some other suitable process.

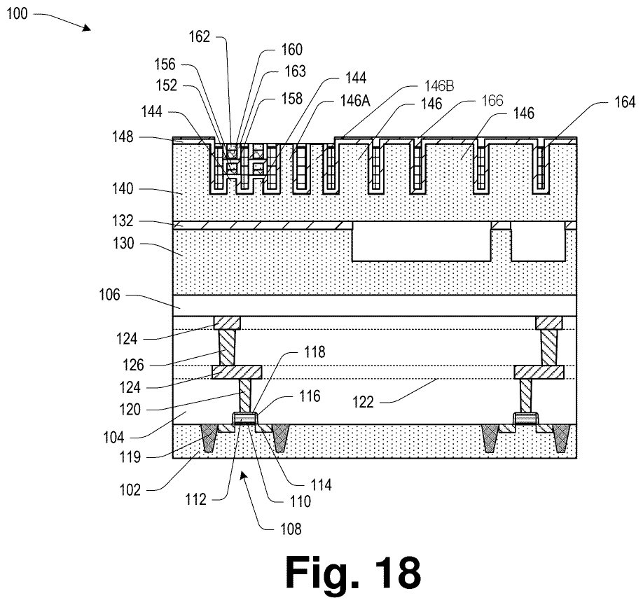

Referring to FIG. 18, portions of the dielectric layers 148, 163, and 166 are removed, in accordance with some embodiments. The portions of the dielectric layers 148, 163, and 166 may be removed by performing an etch process in the presence of a patterned mask. After the removal process, the sacrificial spacer elements 162 and the sacrificial spacer elements 146A, 146B are exposed.

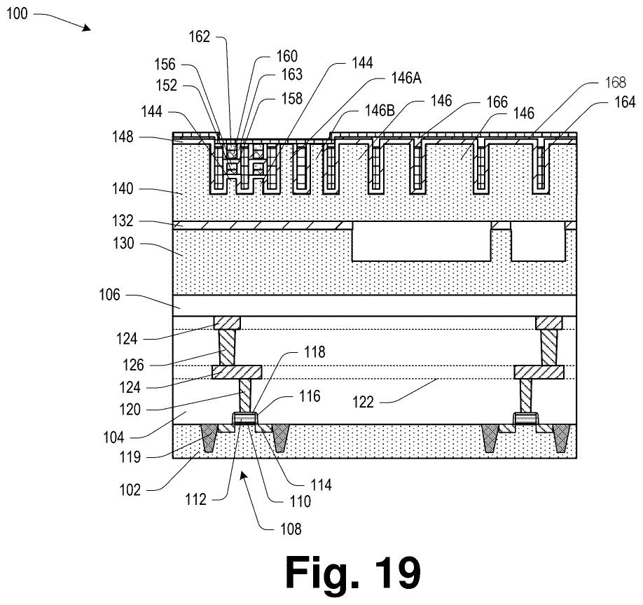

Referring to FIG. 19, a semiconductor layer 168 is formed over the dielectric layers 148, 166 and the sacrificial spacer elements 146A, 146B, 162, in accordance with some embodiments. In some embodiments, the semiconductor layer 168 exhibits different etch selectivity with respect to the sacrificial spacer elements 144, 146A, 146B, 156, 162. The semiconductor layer 168 may comprise polysilicon.

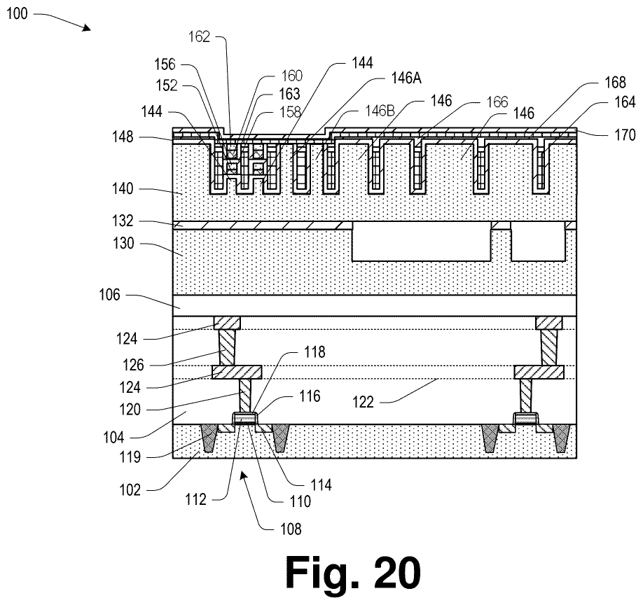

Referring to FIG. 20, a dielectric layer 170 is formed over the semiconductor layer 168, in accordance with some embodiments. In some embodiments, the dielectric layer 170 is silicon dioxide. The dielectric layer 170 may be formed by using, for example, at least one of CVD, PECVD, LPCVD, ALCVD, a spin-on technology, or some other suitable process.

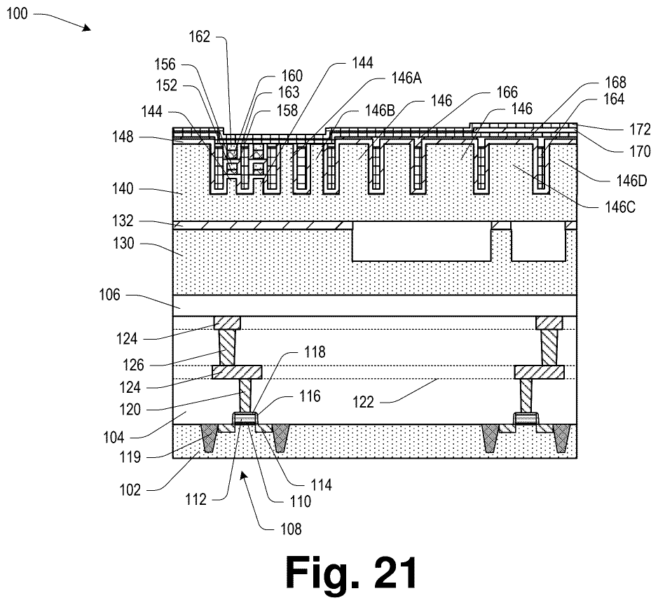

Referring to FIG. 21, a portion of the dielectric layer 170 not disposed over sacrificial spacer elements 146C, 146D is removed to expose portions of the semiconductor layer 168, and a semiconductor layer 172 is formed over the dielectric layer 170 and the semiconductor layer 168, in accordance with some embodiments. In some embodiments, the semiconductor layer 172 comprises polysilicon.

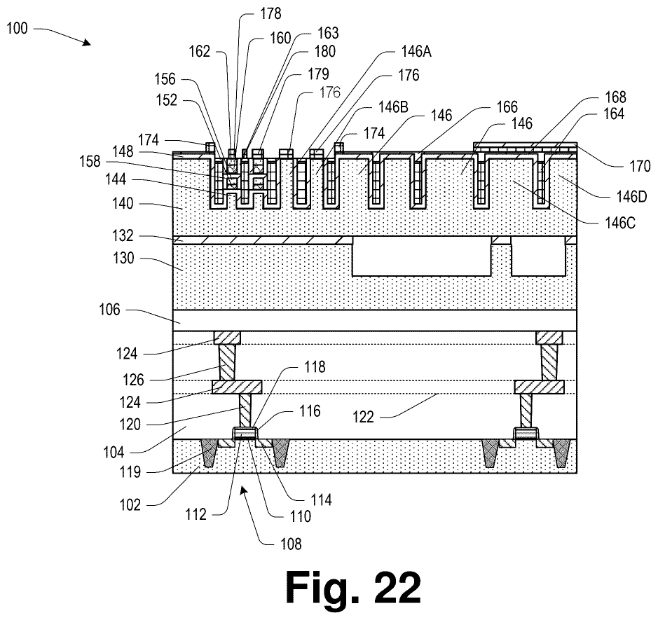

Referring to FIG. 22, portions of the semiconductor layers 168, 172 are removed to define offset structures 174, 176, 178, 179, 180 in remaining portions of the semiconductor layers 168, 172 and to remove a portion of the semiconductor layer 172 over the dielectric layer 170, in accordance with some embodiments. For ease of illustration, the semiconductor layers 168, 172 are illustrated as being merged in the offset structures 174, 176, 178, 179, 180.

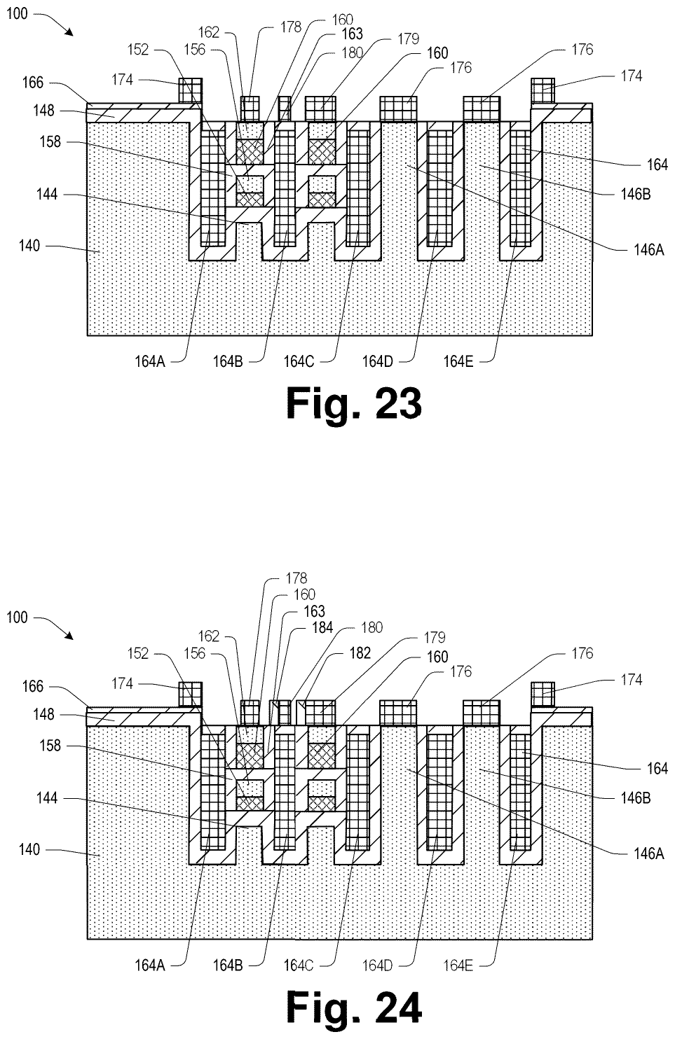

Referring to FIG. 23, an expanded view of a portion of the semiconductor structure 100 illustrating the offset structures 174, 176, 178, 179, 180 is shown, in accordance with some embodiments. The portions of the semiconductor layer 164 adjacent the sacrificial spacer elements 144, 146, 156, 162 define finger elements 164A, 164B, 164C, 164D, 164E of comb structures of the MEMS device. The offset structures 174 are over the dielectric layer 166, the offset structures 176 are over the sacrificial spacer elements 146A, 146B, the offset structures 178, 179 are over the conductive elements 160, and the offset structure 180 is over the finger element 164B.

Referring to FIG. 24, sidewall spacers 182, 184 are formed on the offset structures 179, 180, respectively, in accordance with some embodiments. In some embodiments, the sidewall spacers 182, 184 are formed by depositing a layer of dielectric material and performing an etch process in the presence of a patterned mask to remove portions of the dielectric material disposed on surfaces other than the sidewalls of the offset structures 179, 180. In some embodiments, the sidewall spacers 182, 184 comprise silicon dioxide or another suitable dielectric material.

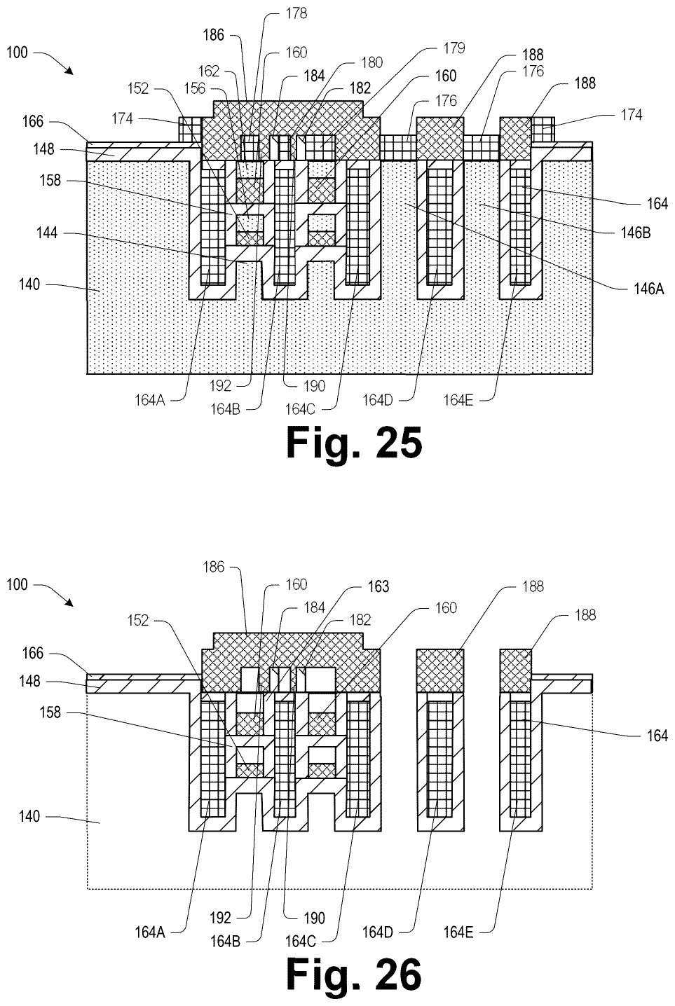

Referring to FIG. 25, a conductive cap structure 186 is formed over the offset structures 176, 178, 179 180 and the finger elements 164A, 164B, 164C and conductive cap structures 188 are formed over the finger elements 164D, 164E, in accordance with some embodiments. The conductive cap structures 186, 188 may be formed by forming a conductive layer over the over the dielectric layer 166, the offset structures 174, 176, 178, 179, 180 and the finger elements 164A, 164B, 164C, 164D, 164E and performing an etch process in the presence of a patterned mask to remove portions of the conductive layer over the dielectric layer 166 and the offset structures 174, 176. The conductive layer may be formed using a CVD process, a PVD process, a plating process, or some other suitable process. In some embodiments, the conductive cap structures 186, 188 comprise aluminum. The conductive cap structure 186 comprises a conductive element 190 adjacent the sidewall spacer 182 and a conductive element 192 adjacent the sidewall spacer 184.

Referring to FIG. 26, the sacrificial spacer elements 144, 146A, 146B, 156, 162 and the offset structures 174, 176, 178, 179, 180 are removed, in accordance with some embodiments. The sacrificial spacer elements 144, 146A, 146B, 156, 162 and the offset structures 174, 176, 178, 179, 180 may be removed using one or more selective etch processes, such as wet etch processes or ashing processes.

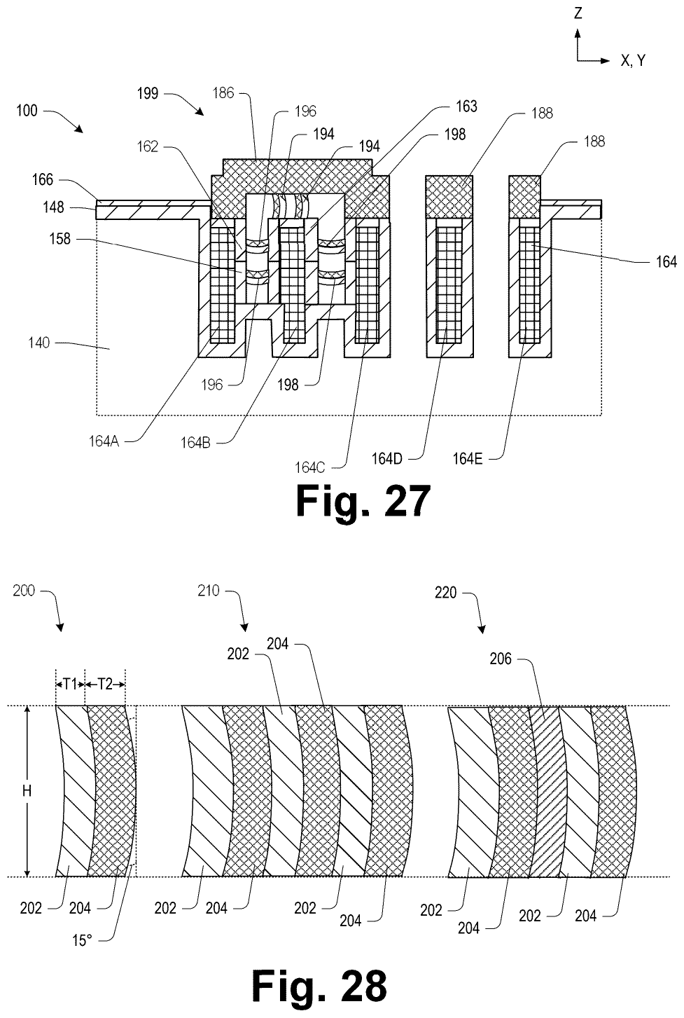

Referring to FIG. 27, an annealing process is performed to form springs 194 spanning between the conductive cap structure 186 and the finger element 164B, springs 196 spanning between the finger elements 164A, 164B, and springs 198 spanning between the finger elements 164B, 164C, in according with some embodiments. The springs 194 are formed from the conductive elements 190, 192 and the sidewall spacers 182, 184. The springs 196, 198 are formed from the conductive elements 152, 160 and horizontal portions of the dielectric layers 148, 158 adjacent the conductive elements 152, 160. A spacing between the springs 194 is about 1.0 μm, corresponding to a critical dimension (CD) of the patterning processes performed in to form the offset structures 179, 180 and the sidewall spacers 182, 184. The CD may be scalable.

The finger elements 164A, 164B, 164C, 164D, 164E are part of a MEMS structure 199. The finger elements 164A, 164C are connected to the conductive cap structure 186 are stationary elements of the MEMS structure 199. The finger element 164B is one of a plurality of moveable elements of the MEMS structure 199. The finger elements 164A, 164B, 164C, 164D, 164E may be part of comb structures, where the stationary finger elements 164A, 164C and the moveable finger elements 164B are interleaved. The springs 196, 198 reduce movement of the moveable finger element 164B from vibration in the lateral direction (x or y direction), and the springs 194 reduce movement of the moveable finger element 164B from vibration in the vertical direction (z direction). Additional springs may be formed using the techniques described herein to provide additional springs that span between the stationary finger elements 164A, 164C and the moveable finger element 164B in the lateral direction that is not visible in FIG. 27 but is perpendicular to the illustrated lateral direction.

Referring to FIG. 28, a diagram illustrating springs 200, 210, 220, is provided, in accordance with some embodiments. The springs 194, 196, 198 may have a structure similar to any of the springs 200, 210, 220. The spring 200 comprises a dielectric layer 202 and a conductive layer 204, such as a metal layer (aluminum). During the annealing process of FIG. 27, compressive stress is induced in the dielectric layer 202 and tensile stress is induced in the conductive layer 204. The competing stresses create a spring-like behavior for the composite structure including the dielectric layer 202 and the conductive layer 204. In some embodiments, stress angle of the spring 200 is about 15°. The stress angle may change as a function of the operating temperature of a device including the semiconductor structure 100, for example, the stress angle may increase with temperature. The Young's modulus of the springs 200 210, 220 may be at least about 70 GPa. In some embodiments, a thickness, T1, of the dielectric layer 202 and a thickness, T2, of the conductive layer 204 are about 0.3 μm-0.7 μm, such as 0.5 μm. A height, H, of the springs 200, 210, 220 may be about 1.4 μm-2 μm, such as 1.6 μm. The height, H, may be scalable. The thicknesses T1, T2 may not be the same. In some embodiments, the thickness T1 of the dielectric layer 202 is at least 50% of the thickness T2 of the conductive layer 204 to distinguish from any native dielectric layer that may form on the exposed conductive material of the conductive layer 204 during process, such as aluminum oxide where the conductive layer 204 comprises aluminum. In some embodiments, the dielectric layer 202 comprises silicon and oxygen. The thicknesses T1, T2 may not be uniform for different layers 202, 204 in the same spring 200, 210, 220. For example, the thickness of the end layers of the dielectric layer 202 and/or the conductive layer 204 of the spring 210, 220 may be greater than the thicknesses of the dielectric layers 202 and/or the conductive layers 204 between the end layers. The thicknesses T1, T2 may be non-uniform across the height, H. For example, the end portions of a layer 202, 204 may be thicker than the middle portion of the layer 202, 204, where the middle portions of the layers 202, 204 may have a combined thickness of >1p m and the end portions of the layers 202, 204 may have a combined thickness of >2 μm.

The spring 210 comprises a stack of alternating dielectric layers 202 and conductive layers 204. The number of layers may not be the same, and any number of layers may be used. The thicknesses and thickness profiles of the layers 202, 204 may vary.

The spring 220 comprises a stack of alternating pairs of dielectric layers 202 and conductive layers 204 separated by a buffer layer 206. In some embodiments, the buffer layer is an organic material that modulates the stress angle. The number of pairs of layers 202, 204 and intervening buffer layers 206 may vary. The thicknesses and thickness profiles of the layers 202, 204, 206 may vary.

Providing springs 194, 196, 198 between stationary elements 164A, 164C and moveable elements 164B of a MEMS structure 199 reduces the susceptibility of the MEMS structure 199 from vibration. Reducing susceptibility of the MEMS structure 199 to vibration increases the accuracy of the MEMS structure 199.

In some embodiments, a micro-electromechanical systems (MEMS) structure is provided. The MEMS structure includes a first stationary element, a second stationary element, a cap structure connecting the first stationary element and the second stationary element, and a moveable element between the first stationary element and the second stationary element and under the cap structure. A first spring includes a first dielectric layer and a first conductive layer and spans between the cap structure and the moveable element. A second spring includes a second dielectric layer and a second conductive layer and spans between the first stationary element and the moveable element. The first dielectric layer and the second dielectric layer comprise silicon and oxygen.

In some embodiments, a MEMS structure includes a first stationary element, a second stationary element, a cap structure connecting the first stationary element and the second stationary element, and a moveable element between the first stationary element and the second stationary element and under the cap structure. A first spring includes a first tensile layer and a first compressive layer and spans between the cap structure and the moveable element. A second spring includes a second tensile layer and a second compressive layer and spans between the first stationary element and the moveable element. The first tensile layer has a first thickness and the first compressive layer has a second thickness of at least 50 percent of the first thickness.

In some embodiments, a method for forming a semiconductor structure is provided. The method includes forming a first stationary element, forming a second stationary element, forming a cap structure connecting the first stationary element and the second stationary element, and forming a moveable element between the first stationary element and the second stationary element and under the cap structure. A first sacrificial spacer element is formed between the first stationary element and the moveable element. A first dielectric layer spanning between the cap structure and the moveable element is formed. A first conductive layer adjacent the first dielectric layer and spanning between the cap structure and the moveable element is formed. A second dielectric layer is deposited over the first sacrificial spacer element and spans between the first stationary element and the moveable element. A second conductive layer is formed over the second dielectric layer and spans between the first stationary element and the moveable element. The first sacrificial spacer element is removed. An annealing process is performed to induce a tensile stress in the first conductive layer and the second conductive layer and to induce a compressive stress in the first dielectric layer and the second dielectric layer to form a first spring including the first dielectric layer and the first conductive layer and a second spring including the second dielectric layer and the second conductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as CVD, for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A micro-electromechanical systems (MEMS) structure, comprising:
a first stationary element;
a second stationary element;
a cap structure connecting the first stationary element and the second stationary element;
a moveable element between the first stationary element and the second stationary element and under the cap structure;
a first spring comprising a first dielectric layer and a first conductive layer and spanning between the cap structure and the moveable element; and
a second spring comprising a second dielectric layer and a second conductive layer and spanning between the first stationary element and the moveable element, wherein:
the first dielectric layer and the second dielectric layer comprise silicon and oxygen.

2. The MEMS structure of claim 1, comprising:
a third spring comprising a third dielectric layer and a third conductive layer and spanning between the second stationary element and the moveable element, wherein:
the third dielectric layer comprises silicon and oxygen.

3. The MEMS structure of claim 1, wherein:
the first conductive layer has a first thickness, and
the first dielectric layer has a second thickness of at least 50 percent of the first thickness.

4. The MEMS structure of claim 1, comprising:
a third spring adjacent the first spring and spanning between the cap structure and the moveable element; and
a fourth spring adjacent the second spring and spanning between the first stationary element and the moveable element.

5. The MEMS structure of claim 1, wherein:
the first spring comprises a third dielectric layer adjacent the first conductive layer and a third conductive layer adjacent the third dielectric layer.

6. The MEMS structure of claim 1, wherein:
the first spring comprises a buffer layer adjacent the first conductive layer, a third dielectric layer adjacent the buffer layer and a third conductive layer adjacent the third dielectric layer.

7. The MEMS structure of claim 1, wherein:
the first conductive layer exhibits tensile stress, and
the first dielectric layer exhibits compressive stress.

8. A micro-electromechanical systems (MEMS) structure, comprising:
a first stationary element;
a second stationary element;
a cap structure connecting the first stationary element and the second stationary element;
a moveable element between the first stationary element and the second stationary element and under the cap structure;
a first spring comprising a first tensile layer and a first compressive layer and spanning between the cap structure and the moveable element; and
a second spring comprising a second tensile layer a second compressive layer and spanning between the first stationary element and the moveable element, wherein:
the first tensile layer has a first thickness and the first compressive layer has a second thickness of at least 50 percent of the first thickness.

9. The MEMS structure of claim 8, comprising:
a third spring comprising a third compressive layer and a third tensile layer and spanning between the second stationary element and the moveable element.

10. The MEMS structure of claim 8, comprising:
a third spring adjacent the first spring and spanning between the cap structure and the moveable element; and
a fourth spring adjacent the second spring and spanning between the first stationary element and the moveable element.

11. The MEMS structure of claim 8, wherein:
the first spring comprises a third tensile layer adjacent the first compressive layer and a third compressive layer adjacent the third tensile layer.

12. The MEMS structure of claim 8, wherein:
the first spring comprises a buffer layer adjacent the first tensile layer, a third compressive layer adjacent the buffer layer and a third tensile layer adjacent the third compressive layer.

13. A method for forming a semiconductor structure, comprising:
forming a first stationary element;
forming a second stationary element;
forming a cap structure connecting the first stationary element and the second stationary element;
forming a moveable element between the first stationary element and the second stationary element and under the cap structure;
forming a first sacrificial spacer element between the first stationary element and the moveable element;
forming a first dielectric layer spanning between the cap structure and the moveable element;
forming a first conductive layer adjacent the first dielectric layer and spanning between the cap structure and the moveable element;
depositing a second dielectric layer over the first sacrificial spacer element spanning between the first stationary element and the moveable element;
forming a second conductive layer over the second dielectric layer and spanning between the first stationary element and the moveable element;
removing the first sacrificial spacer element; and
performing an annealing process to induce a tensile stress in the first conductive layer and the second conductive layer and to induce a compressive stress in the first dielectric layer and the second dielectric layer to form a first spring comprising the first dielectric layer and the first conductive layer and a second spring comprising the second dielectric layer and the second conductive layer.

14. The method of claim 13, comprising:
forming a second sacrificial spacer element between the second stationary element and the moveable element;
depositing a third dielectric layer over the second sacrificial spacer element spanning between the second stationary element and the moveable element; and
forming a third conductive layer over the third dielectric layer and spanning between the second stationary element and the moveable element, wherein:
performing the annealing process comprises:
performing the annealing process to induce a tensile stress in the third conductive layer and to induce a compressive stress in the third dielectric layer to form a third spring comprising the third conductive layer and the third dielectric layer and spanning between the second stationary element and the moveable element.

15. The method of claim 13, comprising:
forming a second sacrificial spacer element over the second conductive layer;
depositing a third dielectric layer over the second sacrificial spacer element;
forming a third conductive layer over the third dielectric layer; and
removing the second sacrificial spacer element prior to performing the annealing process, wherein:
performing the annealing process comprises:
performing the annealing process to induce a tensile stress in the third conductive layer and to induce a compressive stress in the third dielectric layer to form a third spring comprising the third dielectric layer and the third conductive layer and spanning between the first stationary element and the moveable element.

16. The method of claim 13, wherein depositing the first dielectric layer comprises:
depositing the first dielectric layer comprising silicon and oxygen.

17. The method of claim 13, wherein:
forming the first conductive layer comprises forming the first conductive layer having a first thickness, and
forming the first dielectric layer comprises forming the first dielectric layer having a second thickness of at least 50 percent of the first thickness.

18. The method of claim 13, comprising:
forming a first offset structure over the moveable element;
forming a first sidewall spacer adjacent the first offset structure to define the first dielectric layer;
forming the cap structure over the first offset structure, the cap structure comprising a first conductive element adjacent the first sidewall spacer to define the first conductive layer; and
removing the first offset structure prior to performing the annealing process.

19. The method of claim 18, comprising:
forming a second sacrificial spacer element between the second stationary element and the moveable element;
forming a second offset structure over the second sacrificial spacer element;
forming a second sidewall spacer adjacent the second offset structure;
forming the cap structure over the first offset structure and the second offset structure, the cap structure comprising a second conductive element adjacent the second sidewall spacer; and
removing the second offset structure prior to performing the annealing process, wherein:
performing the annealing process comprises:
performing the annealing process to induce a tensile stress in the second conductive element and to induce a compressive stress in the second sidewall spacer to form a third spring comprising the second conductive element and the second sidewall spacer and spanning between the cap structure and the moveable element.

20. The method of claim 13, wherein:
forming the first conductive layer and forming the first dielectric layer comprises forming a stack of alternating conductive layers and dielectric layers; and
performing the annealing process comprises performing the annealing process to induce tensile stress in the conductive layers in the stack and to induce compressive stress in the dielectric layers in the stack.
